(19) United States
(12) Patent Application Publication
(10) Pub. No.: US 2009/0294921 A1
(43) Pub. Date: Dec. 3, 2009

(54) SEMICONDUCTOR DEVICE COMPRISING METAL LINES WITH A SELECTIVELY FORMED DIELECTRIC CAP LAYER

(76) Inventors: Michael Grillberger, Radebeul (DE); Matthias Lehr, Dresden (DE)

Correspondence Address: WILLIAMS, MORGAN & AMERSON, 10333 RICHMOND, SUITE 1100, HOUSTON, TX, 77042, US

(21) Appl. No.: 12/401,887

(22) Filed: Mar. 11, 2009

(30) Foreign Application Priority Data
May 30, 2008 (DE) 10 2008 026 211.0

(51) Int. Cl. H01L 23/58; H01L 21/469

(52) U.S. Cl. 257/632; 438/759; 257/E21.488

(57) ABSTRACT

A dielectric cap layer of a sophisticated metallization system may be provided in a locally restricted manner so as to enable direct contact of the dielectric material of one metallization layer with a low-k dielectric material of a subsequent metallization layer, which may thus provide enhanced adhesion and overall mechanical integrity.

### BACKGROUND OF THE INVENTION

1. Field of the Invention

Generally, the present disclosure relates to integrated circuits, and, more particularly, to the metallization layers of reduced permittivity by using low-k dielectric materials and dielectric cap layers for confining a top surface of metal lines.

2. Description of the Related Art

In an integrated circuit, a very large number of circuit elements, such as transistors, capacitors, resistors and the like, are formed in or on an appropriate substrate, usually in a substantially planar configuration. Due to the large number of circuit elements and the required complex layout of advanced integrated circuits, the electrical connections of the individual circuit elements are generally not established within the same level on which the circuit elements are manufactured. Typically, such electrical connections are formed in one or more additional “wiring” layers, also referred to as metallization layers. These metallization layers generally include metal-containing lines, providing the inner-level electrical connection, and also include a plurality of inter-level connections, also referred to as vias, filled with an appropriate metal. The vias provide electrical connection between metal lines of two neighboring stacked metallization layers, wherein the metal-containing lines and vias may also be commonly referred to as interconnect structures.

Due to the ongoing demand for shrinking the feature sizes of highly sophisticated semiconductor devices, highly conductive metals, such as copper and alloys thereof, in combination with low-k dielectric materials, have become a frequently used alternative in the formation of metallization layers. Typically, a plurality of metallization layers stacked on top of each other is necessary to realize the connections between all internal circuit elements and I/O (input/output), power and ground pads of the circuit design under consideration. For extremely scaled integrated circuits, the signal propagation delay, and thus the operating speed of the integrated circuit, may no longer be limited by the field effect transistors, but may be restricted, owing to the increased density of circuit elements requiring an even more increased number of electrical connections, by the close proximity of the metal lines, since the line-to-line capacitance is increased, which is accompanied by the fact that the metal lines have a restricted conductivity due to a reduced cross-sectional area. For this reason, traditional dielectrics such as silicon dioxide (k>4) and silicon nitride (k>7) are replaced by dielectric materials having a lower permittivity, which are, therefore, also referred to as low-k dielectrics having a relative permittivity of 3 or less. The reduced permittivity of these low-k materials is frequently achieved by providing the dielectric material in a porous configuration, thereby offering a k-value of significantly less than 3.0, wherein such materials may also be referred to as ultra low-k materials. However, due to the intrinsic properties of the dielectric material, such as a high degree of porosity, the density and mechanical stability or strength may be significantly less compared to the well-approved dielectrics silicon dioxide and silicon nitride.

During the formation of copper-based metallization layers, a so-called damascene or inlaid technique is usually used due to copper's characteristic of not forming volatile etch products when being exposed to well-established anisotropic etch ambients. In addition, copper may also not be deposited with high deposition rates on the basis of well-established deposition techniques usually used for aluminum, such as chemical vapor deposition (CVD). Thus, in the inlaid technique, therefore, the dielectric material is patterned to receive trenches and/or vias, which are subsequently filled with the metal by electrochemical deposition techniques.

As is well known, copper may readily diffuse in a plurality of materials, such as silicon, silicon dioxide, and also in many of the low-k dielectric materials which are typically used in advanced metallization systems. For this reason, a direct contact of copper-based materials with many dielectric materials, such as silicon dioxide and low-k and ultra low-k materials may have to be avoided, thereby requiring appropriate barrier materials, which may provide the desired diffusion blocking effect in order to suppress undue out-diffusion of copper atoms. Furthermore, the corresponding barrier materials may also suppress any interaction of reactive components, such as oxygen, fluorine and the like, which may be present in minute amounts in the surrounding material. For this reason, appropriate conductive barrier materials, such as tantalum, tantalum nitride and the like, may frequently be used in order to appropriately confine the copper metal within vias and metal lines, while also providing a desired mechanical and electrical performance of the metal regions under consideration. That is, although copper may exhibit a significantly reduced resistivity and a higher resistance against electromigration when compared to, for instance, aluminum in advanced semiconductor devices, nevertheless, moderately high current densities may occur during the operation of the device due to the high packing density of the devices, which may also require a corresponding reduction of cross-sectional areas of metal lines in the metallization system. Consequently, electromigration, i.e., migration of copper atoms in the direction of electron flow, may represent one of the major failure mechanisms of advanced semiconductor devices, since an increasing directed diffusion of copper atoms along metal lines and vias may finally result in an increase of the resistance of the corresponding interconnect structure and may finally lead to a total failure, since electromigration may significantly depend on the characteristics of respective interfaces formed with barrier materials, dielectric materials and the like. Thus, well-established conductive barrier materials may provide enhanced strength of the respective bonds in the interface area, thereby making these interfaces less prone to premature electromigration-induced failure. On the other hand, typically, a dielectric barrier or cap layer may be formed on top of the completed metal line, which may concurrently act as an etch stop layer for the patterning of a subsequent metallization layer, while also providing the desired barrier and electromigration characteristics. For example, silicon nitride is a dielectric material that may sufficiently suppress the diffusion of copper and may also result in acceptable electromigration behavior. Other appropriate materials, such as nitrogen-containing silicon carbide and the like, may also be used as efficient cap layers for metal lines.

However, as feature sizes continue to shrink in the device level, reduced dimensions for metal lines and vias may also have to be introduced in combination with further reducing the overall parasitic capacitance, in particular in metallization layers in which the parasitic capacitance between neighboring metal lines may significantly contribute to the overall signal propagation delay. The corresponding dielectric materials of a significantly reduced dielectric constant of less than 3.0 may, however, result in significant yield loss due to mechanical instabilities, as will be described in more detail with reference to FIGS. 1a-1d.

FIG. 1a schematically illustrates a cross-sectional view of a semiconductor device 100 in which a dielectric material with reduced permittivity, for instance with a value of 3.0 and significantly less, may be patterned in accordance with an inlaid technique in which, for instance, a via and a metal line may be patterned and filled in a common process sequence. The semiconductor device 100 comprises a substrate 101 which may represent any appropriate carrier material for forming thereon circuit elements and the like as may be required according to the overall design of the semiconductor device 100. For convenience, any such circuit elements, such as transistors, capacitors, resistors and the like, are not shown. As previously explained, typically one or more metallization layers may be required to provide the electrical connections between the various circuit elements, which may be provided in and above the substrate 101. In the example shown, a first metallization layer 110, which may not necessarily represent the very first metallization level, may be provided and may comprise an appropriate dielectric layer 111, for instance in the form of any appropriate dielectric material, such as silicon dioxide and the like. The dielectric layer 111 may also comprise a low-k dielectric material, depending on the overall device requirements. For example, in complex metallization systems, the parasitic capacitance may not necessarily represent a limitation so that the usage of more mechanically robust dielectric materials, such as silicon dioxide, may be considered appropriate, while, in other metallization levels, such as the metallization layer 120, a low-k dielectric material may have to be provided in order to meet requirements with respect to electrical performance of the metallization layer 120. The dielectric layer 111 comprises a plurality of metal regions, such as a metal line 112, which may comprise a highly conductive metal such as copper, possibly in combination with an appropriate conductive barrier material 112B. For example, the barrier material 112B may be comprised of tantalum and tantalum nitride, thereby providing barrier characteristics, while also enhancing adhesion of the highly conductive metal core 112A with respect to the surrounding dielectric material 111. Furthermore, a dielectric cap layer 113, for instance comprised of silicon nitride, nitrogen-containing silicon carbide and the like, may be formed on the dielectric layer 111 and the metal region 112, thereby forming an interface 113S with the metal region 112, the characteristic of which may have a significant influence on the overall electrical behavior of the metal region 112, as previously described.

The semiconductor device 100 further comprises a dielectric material 121 in the second metallization layer 120, which may represent a low-k dielectric material and which may be comprised of any appropriate material composition, such as silicon-based materials, polymer materials and the like, wherein even a certain degree of porousness may provide a reduced dielectric constant while, however, also resulting in a reduced mechanical stability. It should be appreciated that, in some conventional approaches, the dielectric layer 121 may comprise a surface portion of enhanced mechanical characteristics so as to reduce any damage during the subsequent processing, for instance with respect to etch processes, chemical mechanical polishing processes and the like. For convenience, any such surface layers are not shown in FIG. 1a. Moreover, in this manufacturing stage, an etch mask 102 may be formed above the dielectric layer 121 and may have an opening 102A, which may substantially define the lateral size of a via opening to be formed in the dielectric material 121. The etch mask 102 may comprise a resist material, possibly in combination with an anti-reflective coating (ARC) material, for instance comprised of silicon oxynitride and the like, which may also be used as a hard mask material during the patterning of the dielectric material 121. That is, in sophisticated devices, such as the device 100, typically, a lithography process may be used with a moderately short wavelength of the exposure radiation, thereby also requiring an adapted thickness of the resist material, which may be provided in the form of a positive resist material or a negative resist material, depending on the overall process strategy. However, a thickness of the resist material used in the etch mask 102 may not be sufficient to withstand the etch attack during a subsequent etch process, thereby requiring an additional mask material, which may be reliably patterned on the basis of the previously exposed and developed resist material.

The semiconductor device 100 as shown in FIG. 1a may be formed on the basis of the following conventional process techniques. After preparing any circuit elements in and above the substrate 101, which may be accomplished on the basis of well-established process strategies, one or more metallization layers may be formed, such as the metallization layer 110. For this purpose, an appropriate dielectric material, such as a low-k dielectric material and the like, may be deposited, for instance by CVD and the like, followed by a patterning regime, as may be similarly used for forming the etch mask 102 and patterning the dielectric material 121. Hence, the description of the respective patterning sequence may be omitted. Thus, after patterning the dielectric material 111 so as to obtain an appropriate trench, the barrier material 112 may be deposited, for instance, by sputter deposition, followed by an electrochemical deposition of the material 112A, which may be accomplished by electroless deposition, electroplating and the like, possibly in combination with a preceding deposition of a seed material. Thereafter, any excess material may be removed, for instance, by chemical mechanical polishing (CMP). Next, the dielectric cap layer 113 may be formed, for instance, by plasma-assisted CVD and the like. It should be appreciated that the cap layer 113 may comprise two or more sub-layers, if desired. Thereafter, the low-k dielectric material 121 may be deposited, for instance, by CVD, spin-on techniques and the like, depending on the type of low-k material to be provided. As previously explained, if desired, a surface treatment may be performed or a surface layer may be formed in order to enhance overall mechanical characteristics of the dielectric layer 121. Thereafter, any ARC materials and hard mask materials may be deposited, followed by the deposition of the resist material of the etch mask 102. Thereafter, the resist material may be exposed by using a corresponding lithography mask, which is configured to provide the opening 102A, for instance, on the basis of a positive resist material. That is, in this case, exposed portions of the resist material may undergo a photochemical reaction such that the material portions exposed exceed a certain threshold and may be removed during a subsequent development process. Based on the patterned resist material, the etch mask 102 may be formed and subsequently an appropriate etch ambient may be established so as to etch through the dielectric material while using the dielectric cap layer 113 as an efficient etch stop material.

FIG. 1b schematically illustrates the semiconductor device 100 after the above-described process sequence and after removal of the etch mask 102. As illustrated, a via opening 121A is formed in the dielectric layer 121 and extends into the dielectric cap layer 113.

FIG. 1c schematically illustrates the semiconductor device 100 in a further advanced manufacturing stage. As illustrated, the via opening 121A is filled with a material 104, which may also form an appropriate ARC layer above the dielectric layer 121. For this purpose, typically, appropriate resist materials, polymer materials and the like may be used. Furthermore, a further etch mask 103, for instance in the form of a resist mask, is formed on the material 104 and has an opening 103A, which corresponds to the lateral size of a trench to be formed in the dielectric layer 121 in order to form metal lines for the metallization layer 120.

The device 100 as shown in FIG. 1c may be formed on the basis of well-established techniques, such as the deposition of the material 104, for instance, by spin-on techniques and the like, possibly in combination with a planarization step, followed by a lithography sequence including the deposition of a resist material, such as a positive resist material, and an exposure thereof on the basis of a lithography mask configured to create an opening 103A in resist material after development thereof. With respect to an appropriate resist thickness, as well as exposure wavelength, the same criteria apply as previously explained. Thereafter, an anisotropic etch process may be performed on the basis of well-established techniques, thereby creating a corresponding opening in the dielectric layer 121. Thereafter, the resist mask 103 and the material 104 may be removed and the remaining portion of the layer 113 may be removed within the opening 121A to expose a surface portion of the material 112A.

It should be appreciated that other patterning regimes may be used, for instance single damascene processes, in which the via opening 121A may be formed and filled in a separate process technique and thereafter the trench opening may be formed on the basis of the resist mask 103, as described above. After the patterning sequence, the resulting openings, i.e., the via opening 121A and a corresponding trench opening (not shown), may be filled with an appropriate material.

FIG. 1d schematically illustrates the semiconductor device 100 in an advanced manufacturing stage in which a barrier material 122B, for instance in the form of any appropriate conductive material, such as tantalum, tantalum nitride and the like, may be formed within the via opening 121A and a trench opening 121B, while a metal is also formed, thereby defining a metal region 122 within the openings 121B, 121A. The conductive barrier material 122B may be formed by sputter deposition and the like, as previously explained with reference to the barrier material 112B, while the metal for the metal region 122, for instance copper, may be formed on the basis of well-established electrochemical deposition techniques. In order to reliably fill the openings 121A, 121B, a certain amount of excess material 122E is typically provided, which may be subsequently removed by an appropriate planarization technique, which usually comprises a CMP process. During the CMP process 105, portions of the barrier material 122B outside of the metal region 122 may also be removed, thereby establishing electrically insulated metal lines. However, as previously indicated, the reduced mechanical stability of the low-k dielectric material 121 and in particular a reduced adhesion of the material 121 to the dielectric cap layer 113 may result in significant delamination, as indicated as 113A, which may result in reduced reliability and finally in a reduced yield.

Consequently, great efforts are being made in developing new materials for the dielectric cap layer 113 so as to provide enhanced adhesion, thereby requiring significant modifications of the overall process sequences, while possibly also negatively affecting the barrier, etch stop and other characteristics of the dielectric cap layer 113.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to semiconductor devices and methods in which mechanical stability of a metallization system in sophisticated semiconductor devices may be enhanced by increasing the adhesion of a low-k dielectric material to an underlying interlayer dielectric material by providing a corresponding dielectric cap layer in a spatially restricted manner so that significant portions of the low-k dielectric material may not be in contact with the dielectric cap layer. In this manner, the overall mechanical stability may be increased, since the various interlayer dielectric materials of the adjacent metallization levels may generally have an enhanced adhesion to each other so that the provision of interface areas between the two subsequent dielectric layers may thus result in an overall enhanced stability, while, at the same time, well-established dielectric cap materials may be used, which may be substantially restricted to the metal line. Consequently, enhanced electromigration characteristics may be maintained and a high degree of compatibility with well-established processes and materials may also be provided.

One illustrative method disclosed herein relates to forming a metallization layer for semiconductor devices. The method comprises forming a dielectric cap layer on a dielectric layer and a metal region formed in the dielectric layer, wherein the dielectric cap layer and the metal region form an interface. Moreover, the method comprises removing the dielectric cap layer from at least a portion of the dielectric layer while maintaining the interface.

A further illustrative method disclosed herein comprises forming a dielectric cap layer on a dielectric layer of a metallization layer of a semiconductor device, wherein the dielectric layer comprises a metal region forming an interface with the dielectric cap layer. The method further comprises forming a mask above the dielectric cap layer to cover at least the metal region. Finally, the method comprises removing the dielectric cap layer from a portion of the dielectric layer that is not covered by the mask.

An illustrative semiconductor device disclosed herein comprises a low-k dielectric material formed above a substrate and a plurality of metal lines formed in the low-k dielectric material. Furthermore, the semiconductor device comprises a dielectric cap layer formed on the metal lines to form an interface with each of the metal lines, wherein the dielectric cap layer extends laterally from each of the metal lines with a distance that is less than one half of a spacing between two laterally adjacent metal lines.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1d schematically illustrate cross-sectional views of a semiconductor device during various manufacturing stages in forming a metallization layer on the basis of a dielectric cap layer, according to conventional strategies;

FIGS. 2a-2d schematically illustrate cross-sectional views of a semiconductor device during various manufacturing stages when forming a dielectric cap layer and patterning the same on the basis of a mask, according to illustrative embodiments;

FIGS. 2e-2f schematically illustrate cross-sectional views of the semiconductor device during various manufacturing stages in which a mask for patterning the dielectric cap layer may be formed on the basis of a similar lithography sequence as may be used for forming an underlying metal region, according to further illustrative embodiments;

FIGS. 2g-2j schematically illustrate cross-sectional views of the semiconductor device during various manufacturing stages in which the dielectric cap layer may be patterned on the basis of a self-aligned process strategy, according to still further illustrative embodiments; and

FIGS. 2k-2l schematically illustrate a cross-sectional view and a top view, respectively, of the semiconductor device including metal lines having a dielectric cap layer that is spatially restricted to enhance overall mechanical stability, according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure relates to semiconductor devices and methods of forming the same, in which a dielectric cap layer which may be used for confining a metal, acting as an etch stop material and the like, during the formation of complex metallization systems, may be spatially restricted to enable direct contact of the interlayer dielectric material of a lower-lying metallization level and the interlayer dielectric material of the subsequent metallization level, thereby enhancing adhesion between the dielectric materials of adjacent metallization layers. The dielectric cap layer may be formed in a spatially restricted manner by lithography, wherein, in some illustrative embodiments, the same lithography mask may be used, thereby not unduly contributing to overall process complexity. For example, a mask may be formed on the basis of the lithography mask, previously used for forming the trenches for the metal lines of the lower-lying metallization layer wherein, if desired, process parameters may be adjusted to obtain greater lateral dimensions in order to provide a reliable coverage of the metal region by the mask. In other illustrative embodiments, a substantially self-aligned process sequence may be used in patterning the dielectric cap layer, thereby avoiding additional lithography steps, which may thus result in reduced overall process costs.

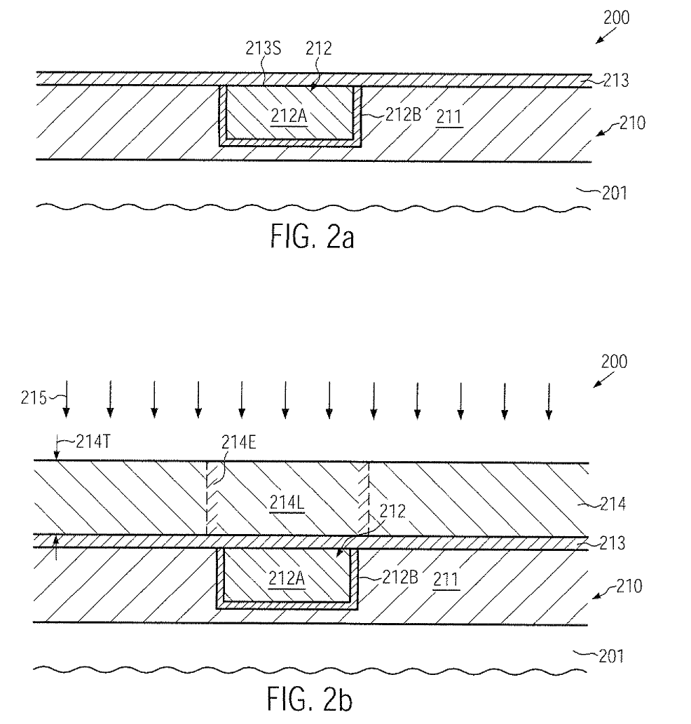

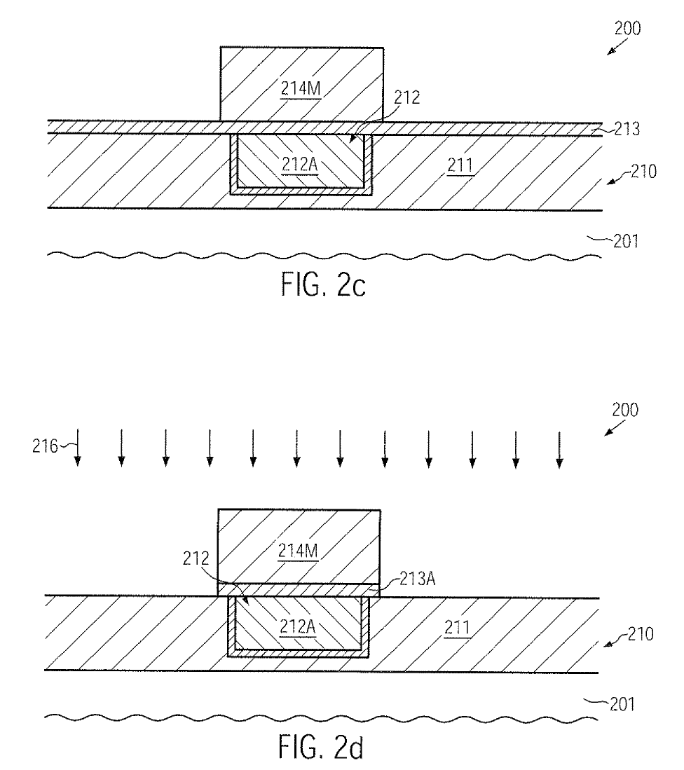

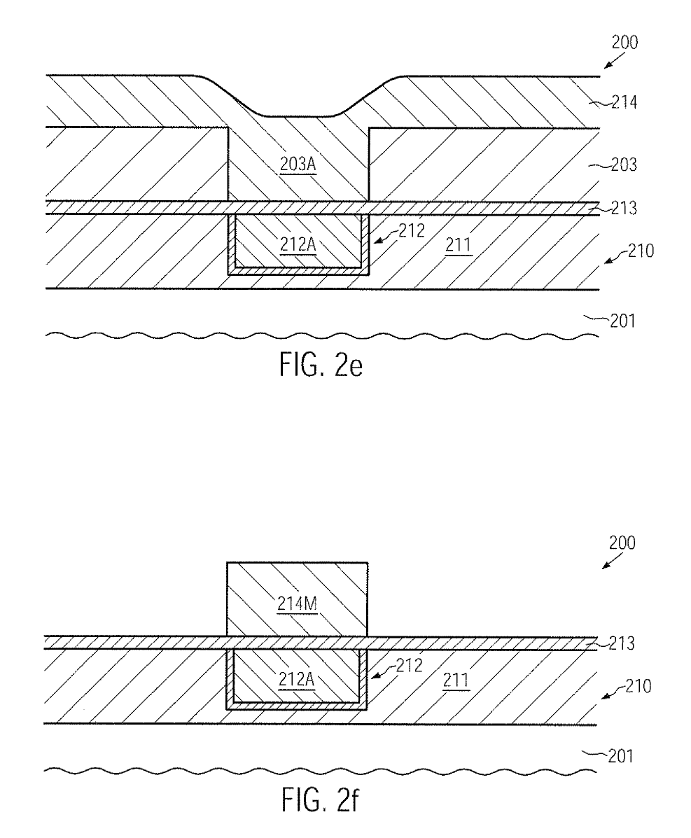

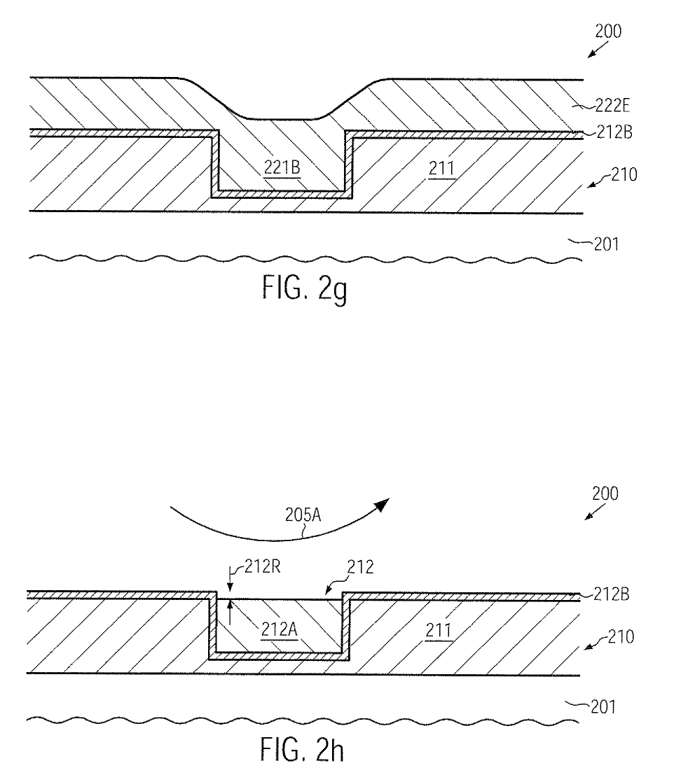

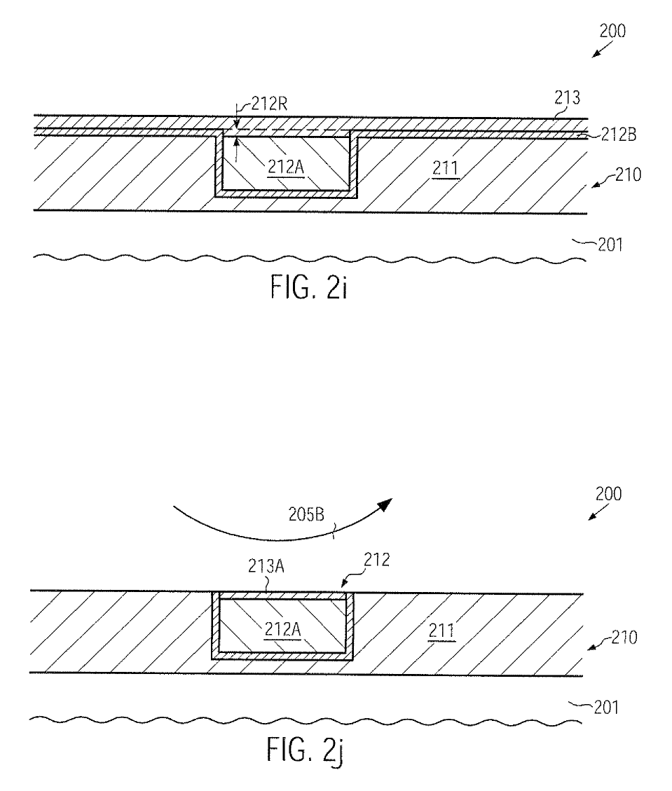

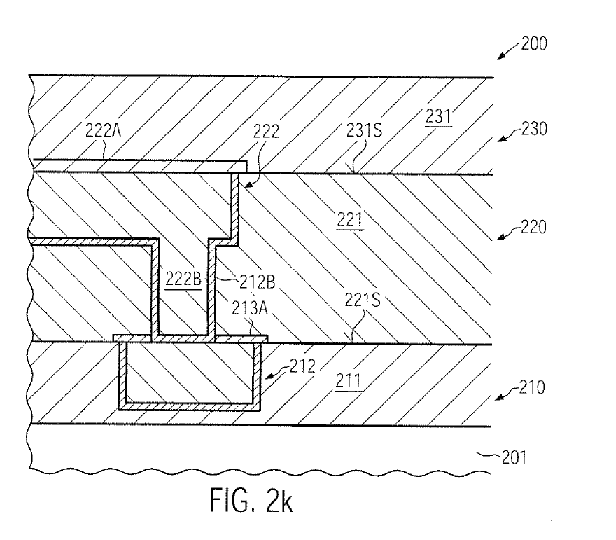

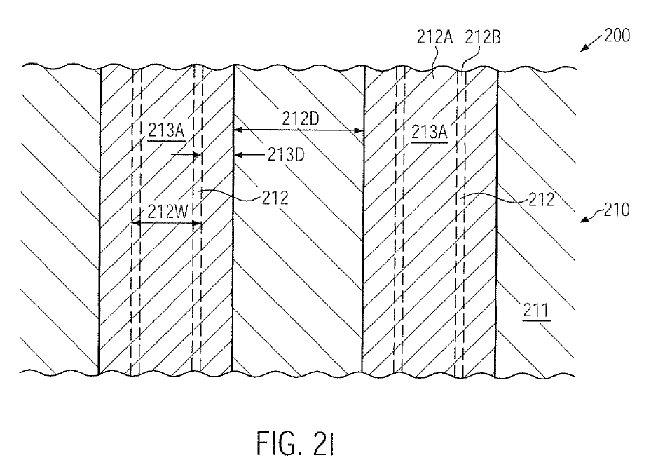

FIG. 2a schematically illustrates a semiconductor device 200 at a certain manufacturing stage in which a first metallization layer 210 may be provided above a substrate 201. The substrate 201 may represent any appropriate carrier material for forming thereabove a metallization system for a semiconductor device in which low-k dielectric materials may have to be provided in view of overall electrical performance of the metallization system under consideration. For example, the substrate 201 may represent a semiconductor substrate, an insulating substrate and the like, above which may be formed a semiconductor layer (not shown), in and above which circuit elements, such as transistors and the like, may be provided. In other cases, respective circuit elements may not be included in the substrate 201, for instance, if the metallization system including the metallization layer 210 may be formed separately from a corresponding device layer of a microstructure device or a semiconductor device. For example, when corresponding circuit elements may be provided in and above the substrate 201, critical dimensions thereof, such as a gate length of field effect transistors, may be approximately 50 nm and less, thereby typically also requiring sophisticated patterning regimes and materials in the metallization layers, such as the layer 210. Furthermore, in the manufacturing stage shown, the metallization layer 210 may comprise a dielectric material 211, which may comprise a low-k dielectric material, i.e., a material having a dielectric constant of 3.0 and less. The dielectric layer 211 may be referred to as interlayer dielectric material, since it may represent the major portion formed between laterally adjacent metal lines and metal regions, such as a metal line 212, of the metallization layer 210. Hence, the metal lines 212 may be considered as metal layers while the dielectric material 211 may be considered as the interlayer material thereof. The metal line 212 may comprise any appropriate metal 212A, such as copper, copper alloys, silver and aluminum and the like, depending on the overall device requirements. Furthermore, in the embodiment shown, a barrier material 212B may be provided in the metal line 212, wherein the barrier material 212B may represent a conductive material providing the desired adhesion, diffusion blocking characteristics, electromigration performance and the like, as is also previously explained with reference to the semiconductor device 100. Furthermore, a dielectric cap layer 213 is formed on the dielectric layer 211 and the metal line 212, thereby defining an interface 213S with the metal region 212. It should be appreciated that the metal region 212 may comprise, in addition to the dielectric cap layer 213, a conductive cap layer, for instance in the form of an alloy and the like, to further enhance the overall electromigration performance at the interface 213S. As previously indicated, the dielectric cap layer 213 may be provided in the form of any appropriate material composition, such as silicon nitride, nitrogen-containing silicon carbide, silicon carbide, a mixture of two or more of these materials and the like.

The semiconductor device 200 as shown in FIG. 2a may be formed on the basis of substantially the same process techniques as previously described with reference to the device 100 when referring to the metallization layers 110 and 120. However, contrary to the conventional process strategy, the dielectric cap layer 213 may be patterned so as to expose significant portions of the dielectric material 211 prior to forming a further metallization layer.

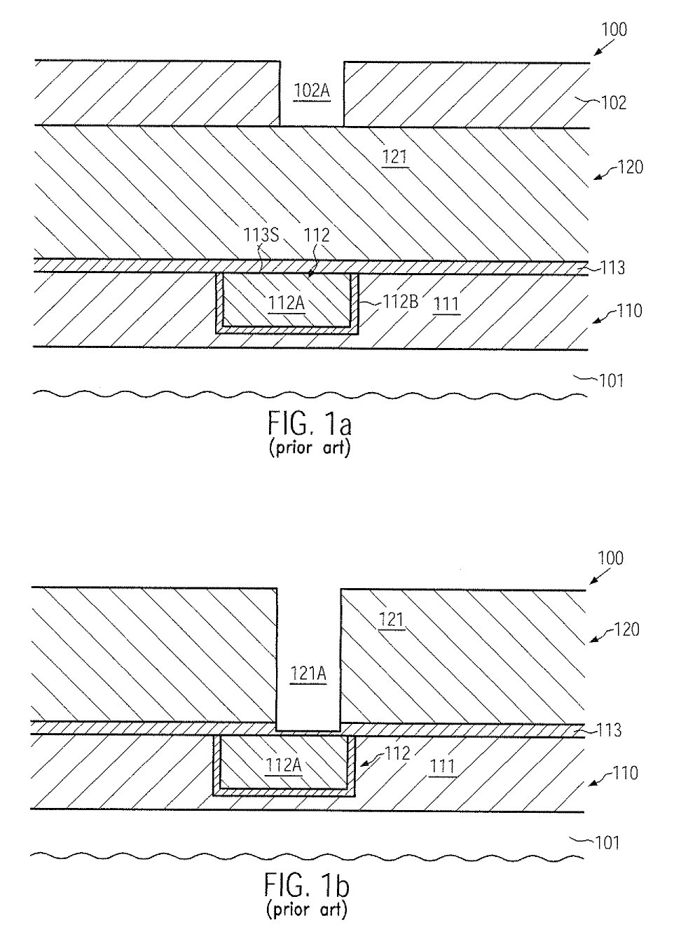

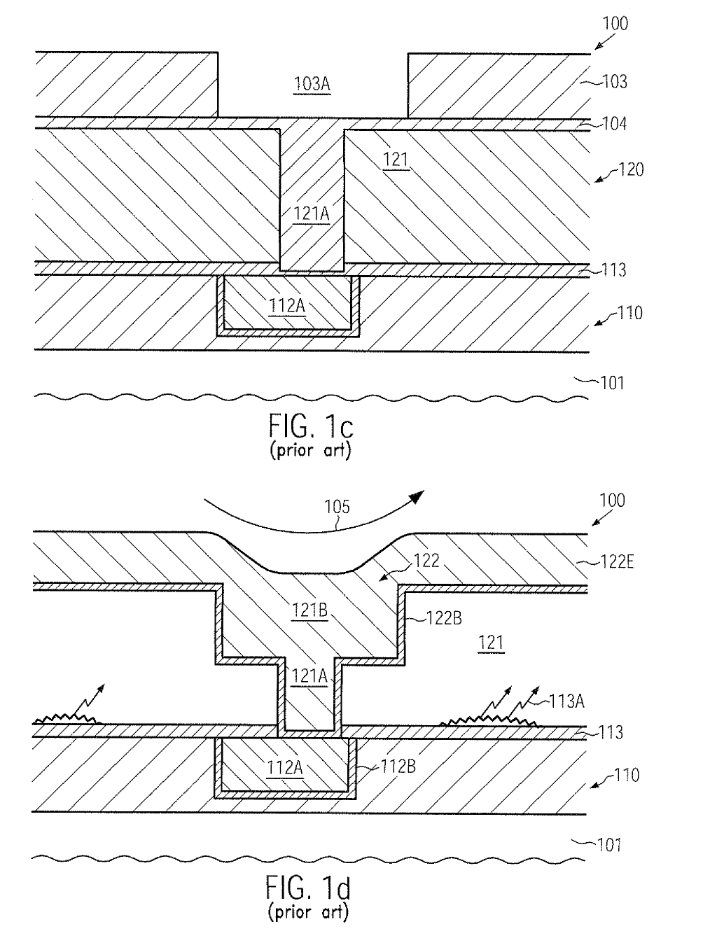

FIG. 2b schematically illustrates the device 200 in a further advanced manufacturing stage. As illustrated, a mask layer 214, for instance comprising a resist material, is formed above the dielectric cap layer 213. For example, the mask layer 214 may represent any appropriate resist material, which may be appropriate for patterning the dielectric cap layer 213 on the basis of an etch mask formed from the layer 214. For this purpose, in some illustrative embodiments (not shown), an appropriate lithography mask may be provided which may enable an exposure of the resist material 214 such that a non-developed portion may be formed above the metal region 212, possibly with lateral dimensions that may be greater than the lateral dimensions of the metal region 212, so as to provide for process margins with respect to alignment accuracy. In other illustrative embodiments, as shown, the resist material of the mask layer 214 may be provided with a photochemical behavior that may be inverse to the photochemical behavior of a resist material which may be used for patterning an opening for the metal region 212. For example, as previously explained with reference to the device 100, when referring to the resist layer 103 (FIG. 1c), a negative resist or positive resist may be used in combination with an appropriate lithography mask in order to obtain a desired opening, such as the opening 103A of FIG. 1c. Consequently, by using a resist material of opposite photochemical behavior, the same lithography mask may be used during an exposure 215 for creating a latent image 214L, which may present a portion that may not be removed during a subsequent development of the exposed layer 214. In some illustrative embodiments, a thickness 214T of the resist layer 214 may be selected to enhance overall performance of the exposure process 215 compared to the exposure conditions during the preceding lithography process for defining an etch mask for the opening of the metal region 212, as is also previously explained with respect to the device 100, since, in the preceding lithography process, the corresponding resist mask may act as an etch mask for etching through a substantial thickness of the dielectric material 211, thereby requiring an appropriately set initial thickness of the resist material. On the other hand, during the exposure 215, the reduced thickness 214T may be used since the corresponding etch mask, i.e., the non-removed portion of the latent image 214L, may be used for an etch process for etching through the dielectric cap layer 213 having a significantly reduced thickness compared to the dielectric layer 211, thereby providing significant reduced overall etch times.

Moreover, during the exposure process 215, the exposure dose may be selected such that a certain degree of overexposure may be generated, thereby also depositing energy at edge regions 214E of the latent image 214L, although the same lithography mask may be used, which would otherwise correspond to a lateral size of the metal region 212. Consequently, a critical threshold of the resist material of the layer 214 may be exceeded or may not be reached, depending on the type of resist material used in the edge regions 214E, thereby obtaining the latent image 214L having increased lateral dimensions, if desired.

FIG. 2c schematically illustrates the semiconductor device 200 in a further advanced manufacturing stage. As illustrated, a mask 214M may be positioned above the metal region 212, wherein the lateral size of the mask 214M may substantially correspond to the latent image 214L (FIG. 2b). The mask 214M may be obtained by developing the exposed mask layer 214 using appropriate process parameters, which may be well established in the art.

FIG. 2d schematically illustrates the semiconductor device 200 during an etch process 216 for effectively removing a portion of the dielectric cap layer 213 that is not covered by the mask 214M. Thus, a spatially restricted cap layer 213A may be provided, which may at least cover the metal region 212 and may possibly extend laterally beyond the metal region 212 so as to provide for a certain process margin, if desired. The etch process 216 may be performed on the basis of plasma-assisted etch recipes, which are well established in the art for a plurality of cap materials such as specified above, while, in other illustrative embodiments, wet chemical etch recipes may be used if sufficient etch selectivity with respect to the underlying dielectric material 211 may be obtained. As previously explained with reference to the device 100, in some illustrative embodiments, an appropriate surface layer of the material 211 may also be provided, for instance, by surface treatment, deposition and the like to enhance overall characteristics of the material 211, however, without unduly modifying the overall dielectric characteristics thereof. In this case, a certain increased etch resistivity may be obtained during the process 216, thereby enhancing the degree of flexibility in selecting an appropriate etch recipe. For example, silicon nitride-based materials may be efficiently removed by a plurality of plasma-assisted chemistries selectively to silicon dioxide-based material, while selective wet chemical etch recipes are also available for these materials. Thereafter, the mask 214M may be removed by well-established resist removal processes and the further processing may be continued by forming a low-k dielectric material and patterning the same to form vias and trench openings, as is also previously explained with reference to the semiconductor device 100 when referring to the metallization layer 120.

With reference to FIGS. 2e-2f, further illustrative embodiments will now be described in which the mask 214M may be formed on the basis of a lithography sequence that may be very similar to the lithography sequence used for patterning the dielectric material 211 to provide an opening for the metal region 212.

FIG. 2e schematically illustrates the semiconductor device 200 with a resist mask 203 having formed therein an opening 203A which may substantially correspond to the metal region 212. Furthermore, a mask layer 214 may be formed above the resist layer 203 so as to substantially completely fill the opening 203A. For example, the mask layer 214 may be provided in the form of a resist material, or any other polymer material and the like, which may be deposited in a highly non-conformal manner.

The patterned resist layer 203 may be formed by depositing an appropriate resist material, which may have the same photochemical response as a resist material previously used for patterning the dielectric layer 211, as is also discussed above. Hence, similar process techniques may be used wherein, also in this case, a reduced layer thickness for the layer 203 may be used in order to enhance overall performance of the lithography process, as previously explained. It should be appreciated that, in some illustrative embodiments, the exposure of the resist layer 203 may be performed on the basis of appropriately selected exposure parameters, such as an increased dose to also provide an increased lateral size of the opening 203A when a corresponding process margin may be desired. For example, appropriate process parameters with respect to exposure dose may be readily established by running appropriate tests to obtain a desired lateral dimension for a given thickness of the resist layer 203. Thereafter, mask material 214 may be deposited and may be subsequently planarized to expose the layer 203, which may then be selectively removed with respect to the remaining material of the mask layer 214 on the basis of any appropriate etch recipe for which appropriate process parameters may be available for a plurality of resist materials, polymer materials and the like.

FIG. 2f schematically illustrates the semiconductor device 200 after the above-described process sequence. Hence, after the selective removal of the resist layer 203, the mask 214M may be formed in accordance with the dimensions of the opening 203A of the metal region 212. Thereafter, the etch process 216 (FIG. 2d) may be performed in order to remove non-covered portions of the dielectric cap layer 213, as previously explained. Thereafter, the further processing may be continued by forming the subsequent metallization level on the basis of a low-k dielectric material.

With reference to FIGS. 2g-2j, further illustrative embodiments will now be described in which the dielectric cap layer may be positioned on the metal region in a substantially self-aligned manner.

FIG. 2g schematically illustrates the semiconductor device 200 in a manufacturing stage in which an opening 221B formed in the dielectric layer 211 is filled with a conductive barrier material 212B and the metal 222E, which may also form excess material above the barrier layer 212B. As previously already explained, the opening 221B may be formed on the basis of lithography techniques as discussed above with reference to the device 100 when referring to the metallization layer 120. Thereafter, the conductive barrier material 212B may be deposited on the basis of any appropriate deposition technique, such as sputter deposition, CVD, self-limiting CVD techniques and the like. Thereafter, the metal layer 222E may be formed by electrochemical deposition techniques.

FIG. 2h schematically illustrates the device 200 in a further advanced manufacturing stage in which a removal process 205A may be performed to remove the excess material 222E and also create a recess 212R in the metal region 212. For example, during the removal process 205A, a CMP process may be performed on the basis of a recipe for preferably removing material of the layer 222E, while using the barrier material 212B as a CMP stop layer. Consequently, by applying an appropriate over-polish time, the recess 212R may be at an upper portion of the metal region 212. In other illustrative embodiments, well-established CMP recipes may be used in which the barrier material 212B may also be used as a stop layer and thereafter an electrochemical etch process may be performed, thereby selectively removing a portion of the material 212A to create the recess 212R.

FIG. 2i schematically illustrates the device 200 in a further advanced manufacturing stage, in which the dielectric cap layer 213 may be formed on the barrier layer 212B and within the recess 212R. For this purpose, the dielectric cap layer 213 may be deposited with a sufficient thickness so as to completely fill the recess 212R, which may be accomplished by providing an increased deposition time while using well-established process parameters.

FIG. 2j schematically illustrates the device 200 during a further removal process 205B, which may comprise a CMP process to remove excess material of the dielectric cap layer 213, thereby forming the spatially restricted cap layer 213A, while also removing the barrier material outside of the metal line 212, thereby forming electrically insulated metal lines in the metallization layer 210. It should be appreciated that the removal process 205B may comprise several CMP steps if the removal rates of the materials 213, 212B may not be compatible. For example, the barrier layer 212B may be removed on the basis of an appropriate process recipe, which may exhibit an increased removal rate for the barrier material 212B compared to the cap layer 213A.

Consequently, the spatially restricted dielectric cap layer 213A may be formed on the basis of a self-aligned manufacturing sequence, while avoiding additional photolithography processes, which may thus contribute to reduced production costs. Thereafter, the further processing may be continued, as described above.

FIG. 2k schematically illustrates the semiconductor device 200 in a further advanced manufacturing stage. As illustrated, a second metallization layer 220 may be formed above the first metallization layer 210 comprising the dielectric material 211 and the spatially restricted dielectric cap layer 213A that covers at least the metal line 212. The second metallization layer 220 may comprise a dielectric material 221, for instance a low-k material or an ultra low-k material, which, due to the spatially restricted dielectric cap layer 213A, may form interface portions 221S with the material 211 between the various metal lines 212 formed in the first metallization layer 210. Consequently, an enhanced mechanical integrity of the stack of the layers 210, 220 may be obtained, since the adhesion of the material 221 to the material 211 may be significantly higher compared to the adhesion of the material 221 to material of the dielectric cap layer 213A, as previously explained. Furthermore, the second metallization layer 220 may comprise metal regions 222, for instance in the form of metal lines connecting one or more of the metal lines 212 in the metallization layer 210 by means of respective vias 222B. The metal region 222 may also comprise the barrier material 212B in combination with a highly conductive metal, such as copper and the like, as previously explained with reference to the metal line 212. Moreover, a dielectric cap layer 222A may be formed on the metal region 222 in the form of a spatially restricted layer in a similar manner as is explained for the layer 213A. Furthermore, the semiconductor device 200 may comprise a further metallization layer 230 including a dielectric material 231, for instance in the form of a low-k dielectric material, which may also connect to material 221 at an interface 231S, wherein, also in this case, enhanced adhesion may be provided due to the spatial restriction of the dielectric cap layer 222A.

With respect to any process techniques for forming the semiconductor device 200 as shown in FIG. 2k, it may be referred to the process techniques described with reference to the device 100, when forming and patterning of dielectric material are concerned. Furthermore, the spatially restricted cap layer 222A may be formed in accordance with the same process strategies as previously described with reference to FIGS. 2a-2j.

FIG. 2L schematically illustrates a top view of the semiconductor device 200 at a manufacturing stage prior to forming the metallization layer 220. As shown, the metallization layer 210 may comprise the dielectric material 211, in which a plurality of the metal lines 212 may be formed, as previously described. Furthermore, the spatially restricted dielectric cap layers 213A may be provided such that at least the metal regions 212A, indicated as dashed lines, may be reliably covered by the cap layers 213A. In the embodiment shown, the cap layers 213A may laterally extend from the metal lines 212 according to a distance 213D, which is less than one half of a distance 212D between adjacent two metal lines 212. In this manner, it is guaranteed that the dielectric material 211 of the metallization layer 210 may come into direct contact with the dielectric material of a subsequent metallization layer, such as the metallization layer 220 between neighboring metal lines 212. In one illustrative embodiment, the distance 213D may be less than a width 212W of each of the metal lines 212.

As a result, the present disclosure provides semiconductor devices and methods of forming the same in which overall mechanical integrity of a metallization layer stack may be enhanced by providing a dielectric cap layer in a locally restricted manner so as to form interfaces between the interlayer dielectric materials of two subsequent metallization layers. The dielectric cap layer may be locally restricted by forming a mask, which may be accomplished, in some illustrative embodiments, by using the same lithography mask as is used for patterning the underlying dielectric material. In other cases, a self-aligned process sequence may be used.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a metallization layer of a semiconductor device, the method comprising:
forming a dielectric cap layer on a dielectric layer and a metal region formed in said dielectric layer, said dielectric cap layer and said metal region forming an interface; and
removing said dielectric cap layer from at least a portion of said dielectric layer while maintaining said interface.

2. The method of claim 1, wherein removing said dielectric cap layer from at least a portion of said dielectric layer comprises forming a mask above said dielectric cap layer to cover at least said metal region and removing a portion of said cap layer not covered by said mask.

3. The method of claim 2, wherein forming said mask comprises forming a resist layer of opposite photochemical response relative to a resist material used for patterning said dielectric layer when forming an opening for said metal region, wherein the method further comprises exposing said resist layer with the same photolithographic mask as used for forming said opening.

4. The method of claim 3, wherein said resist layer is exposed on the basis of an exposure dose so as to obtain a lateral extension of said mask that is greater than a lateral extension of said metal region.

5. The method of claim 3, wherein a thickness of said resist layer is less than a thickness of said resist material used for forming said opening.

6. The method of claim 2, wherein forming said mask comprises forming a resist layer above said cap layer, forming a mask opening in said resist layer that substantially corresponds to said metal region, filling said mask opening with a mask material and removing said resist layer selectively to said mask material.

7. The method of claim 6, wherein said mask opening is formed by using a lithographic mask that is used for forming an opening for said metal region formed in said dielectric layer.

8. The method of claim 1, wherein forming said cap layer comprises forming a recess in said metal region and forming said cap layer so as to at least partially fill said recess.

9. The method of claim 8, wherein removing said dielectric cap layer from at least a portion of said dielectric layer comprising performing a planarization process.

10. The method of claim 9, further comprising forming an opening in said dielectric layer, forming a conductive barrier layer in said opening, filling said opening with a metal and removing excess material of said metal to provide said metal region.

11. The method of claim 10, wherein said recess is formed prior to removing said barrier layer from said dielectric layer outside of said metal region.

12. The method of claim 11, wherein said recess is formed by performing a chemical mechanical planarization process.

13. The method of claim 11, wherein said recess is formed by performing an electrochemical removal process.

14. The method of claim 1, wherein said dielectric layer comprises material having a dielectric constant of approximately 3.0 or less.

15. A method, comprising:
forming a dielectric cap layer on a dielectric layer of a metallization layer of a semiconductor device, said dielectric layer comprising a metal region forming an interface with said dielectric cap layer;
forming a mask above said dielectric cap layer to cover at least said metal region; and
removing said dielectric cap layer from a portion of said dielectric layer that is not covered by said mask.

16. The method of claim 15, further comprising forming said metal region by using a lithography mask and a first resist material having one of a positive and a negative exposure behavior, wherein said mask is formed by using said lithography mask and a second resist material having the other one of said positive and negative exposure behavior.

17. The method of claim 16, wherein a thickness of said second resist material is less than a thickness of said first resist material.

18. The method of claim 17, wherein process parameters of a lithographical process sequence are selected so as to form said mask with a lateral size that is greater than a lateral size of said metal region.

19. A semiconductor device, comprising:
a low-k dielectric material formed above a substrate;
a plurality of metal lines formed in said low-k dielectric material; and
a dielectric cap layer formed on said metal lines so as to form an interface with each of said metal lines, said dielectric cap layer extending laterally from each of said metal lines with a distance that is less than one half of a spacing between two laterally adjacent metal lines.

20. The semiconductor device of claim 19, wherein said dielectric cap layer laterally extends from each of said metal lines with a distance that is less than a width of each of said metal lines.
